(19) United States
(12) Patent Application Publication
(10) Pub. No.: US 2026/0150186 A1
(43) Pub. Date: May 28, 2026

(54) SEMICONDUCTOR MODULE AND METHOD OF MANUFACTURING THE SAME

(71) Applicant: Samsung Electronics Co., Ltd., Suwon-si (KR)

(72) Inventors: Byoungran KO, Suwon-si (KR); Hyun-Jong OH, Suwon-si (KR); Jinkyu YANG, Suwon-si (KR); Jiwon KIM, Suwon-si (KR)

(73) Assignee: Samsung Electronics Co., Ltd., Suwon-si (KR)

(21) Appl. No.: 19/400,549

(22) Filed: Nov. 25, 2025

(30) Foreign Application Priority Data
Nov. 27, 2024 (KR) 10-2024-0172870

(51) Int. Cl. H05K 1/02; H05K 1/11; H05K 3/34

(52) U.S. Cl. CPC H05K 1/0296; H05K 1/117; H05K 3/341; H05K 2201/09036; H05K 2201/10159; H05K 2201/2081

(57) ABSTRACT

Disclosed is a semiconductor module including a module printed circuit board and a semiconductor chip mounted on the module printed circuit board, the module printed circuit board including a substrate including a first surface and a second surface on opposite sides, first horizontal wiring lines on the first surface, and a first solder mask on the first horizontal wiring lines, and the first solder mask is configured to expose a first exposure surface and a second exposure surface of the first surface spaced apart from each other in a first direction.

### CROSS-REFERENCE TO RELATED APPLICATIONS

This application claims priority under 35 U.S.C. § 119 to Korean Patent Application No. 10-2024-0172870 filed on Nov. 27, 2024, in the Korean Intellectual Property Office, the disclosures of which are incorporated by reference herein in their entireties.

### BACKGROUND

Example embodiments of the present disclosure described herein relate to semiconductor modules and methods of manufacturing a semiconductor module.

A semiconductor module may be an electronic component in the form of a package, which includes one or more semiconductor chips, a substrate that supports the same, a wiring line for electrical connection, and external terminals. The semiconductor module may include a central processing unit (CPU) module, a memory module, a power semiconductor module, and the like.

The semiconductor module may have defects due to minute process changes, external environmental factors, and situations occurring in a production line. It is beneficial to respond to occurrence of the defects in the semiconductor module.

### SUMMARY

Example embodiments of the present disclosure provide semiconductor modules that improve defects.

Example embodiments of the present disclosure also provide methods of manufacturing a semiconductor module that improve defects.

However, the problems to be solved are not limited to the above disclosures.

According to some example embodiments, a semiconductor module includes a module printed circuit board and a semiconductor chip mounted on the module printed circuit board, the module printed circuit board including a substrate including a first surface and a second surface on opposite sides, first horizontal wiring lines provided on the first surface, and a first solder mask on the first horizontal wiring lines, and the first solder mask is configured to expose a first exposure surface and a second exposure surface of the first surface spaced apart from each other in a first direction.

According to some example embodiments, a semiconductor module includes a module printed circuit board and semiconductor chips mounted on the module printed circuit board, the module printed circuit board including a substrate including a first surface and a second surface on opposite sides, first horizontal wiring lines and second horizontal wiring lines on the first surface and the second surface, a first solder mask and a second solder mask on the first horizontal wiring lines and the second horizontal wiring lines, and a plurality of edge connectors spaced apart from the semiconductor chips, the first solder mask is configured to expose a first exposure surface and a second exposure surface of the first surface spaced apart from each other in a first direction parallel to the first surface, and the second solder mask is configured to expose a third exposure surface and a fourth exposure surface of the second surface spaced apart from each other in the first direction.

According to some example embodiments, a method of manufacturing a semiconductor module includes forming a preliminary module printed circuit board including a substrate including a first surface and a second surface on opposite sides, first horizontal wiring lines on the first surface, second horizontal wiring lines on the second surface, and a plurality of vias extending in a thickness direction of the substrate, forming a first solder mask and a second solder mask on the first surface and the second surface, respectively, to form a module printed circuit board, and mounting a semiconductor chip on the module printed circuit board, wherein the first solder mask exposes a first exposure surface and a second exposure surface of the first surface spaced apart from each other in a first direction parallel to the first surface.

### BRIEF DESCRIPTION OF THE FIGURES

The above and other objects and features of the present disclosure will become apparent by describing in detail example embodiments thereof with reference to the accompanying drawings.

FIG. 1 is a plan view of a semiconductor module according to some example embodiments.

FIG. 2 is another plan view of the semiconductor module of FIG. 1.

FIG. 3 is a cross-sectional view along line A-A′ of FIG. 1.

FIG. 4 is a plan view corresponding to FIG. 1 for describing a state in which a gripper grips a module printed circuit board.

FIG. 5 is a cross-sectional view corresponding to FIG. 3 for describing the state in which the gripper grips the module printed circuit board.

FIGS. 6 to 8 are cross-sectional views corresponding to line A-A′ of FIG. 1 for describing a method of manufacturing a semiconductor module according to some example embodiments.

FIG. 9 is a plan view of the semiconductor module according to some example embodiments.

FIG. 10 is a plan view corresponding to FIG. 9 for describing the state in which the gripper grips the module printed circuit board.

### DETAILED DESCRIPTION

Hereinafter, example embodiments of the present disclosure will be described clearly and in detail to the extent that those skilled in the art may easily implement the present disclosure.

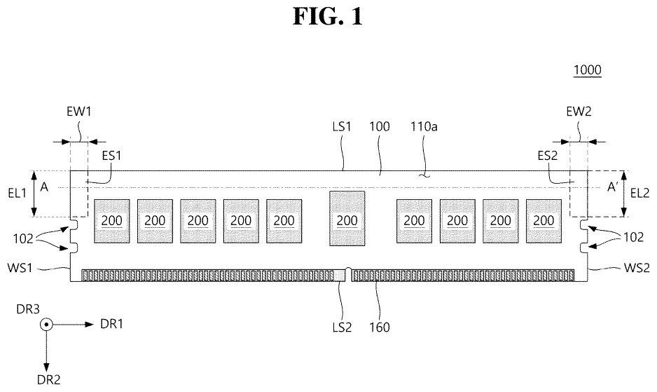

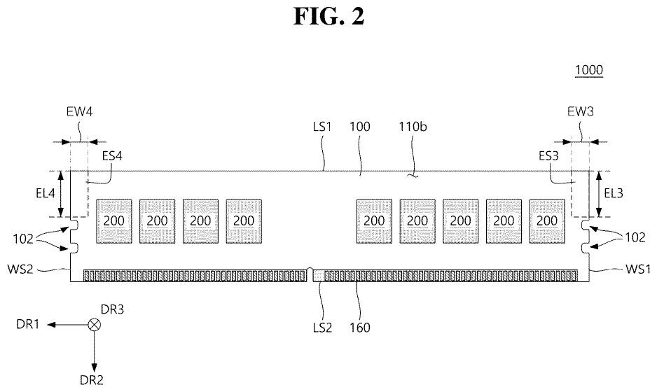

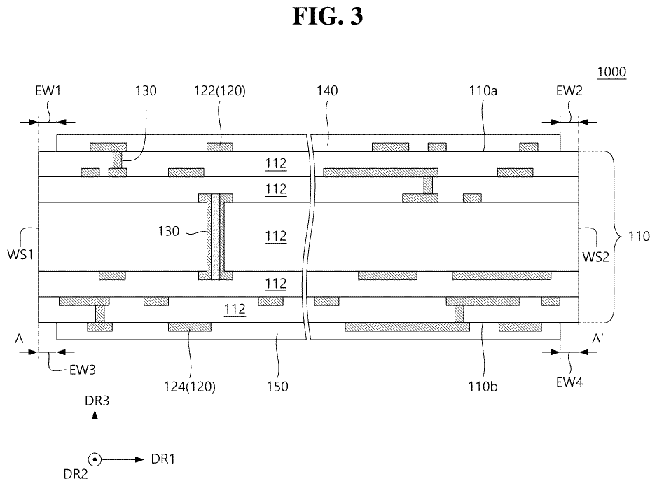

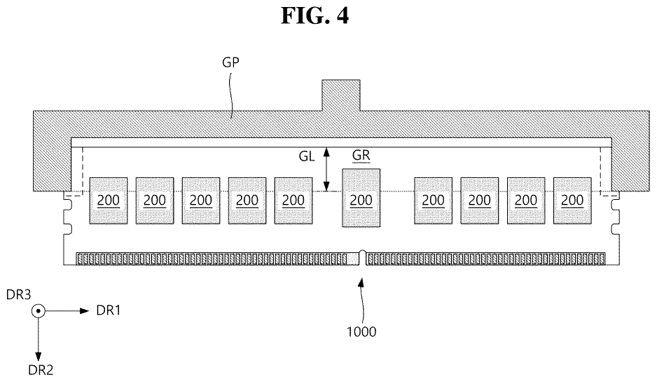

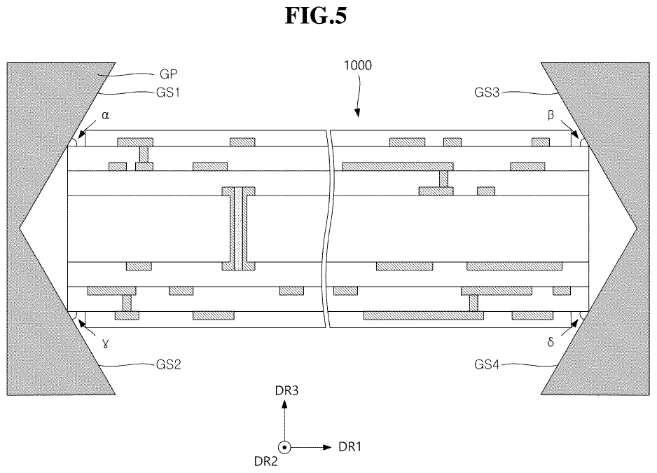

FIG. 1 is a plan view of a semiconductor module according to some example embodiments. FIG. 2 is another plan view of the semiconductor module of FIG. 1. FIG. 3 is a cross-sectional view along line A-A′ of FIG. 1. FIG. 4 is a plan view corresponding to FIG. 1 for describing a state in which a gripper grips a module printed circuit board. FIG. 5 is a cross-sectional view corresponding to FIG. 3 for describing the state in which the gripper grips the module printed circuit board.

Referring to FIGS. 1 to 3, a semiconductor module 1000 may be provided. The semiconductor module 1000 may be used in various computing systems. For example, the semiconductor module 1000 may be used in computing systems such as laptop computers, desktop computers, workstations, server systems, game consoles, industrial computers, network equipment, embedded systems, or high performance computing (HPC) systems. The semiconductor module 1000 may also be used in special-purpose computing systems such as artificial intelligence (AI) accelerators, graphics processing unit (GPU) systems, or storage systems of data centers. The semiconductor module 1000 may include a memory module form having various standards. For example, the semiconductor module 1000 may be any one of a small outline dual in-line memory module (SODIMM), a dual in-line memory module (DIMM), a micro dual in-line memory module (MicroDIMM), a mini dual in-line memory module (MiniDIMM), an unbuffered dual in-line memory module (UDIMM), a registered dual in-line memory module (RDIMM), and a load reduced dual in-line memory module (LRDIMM).

The semiconductor module 1000 may include a module printed circuit board 100 and at least one semiconductor chip 200. The module printed circuit board 100 may be a substrate structure that physically supports and electrically connects the semiconductor chip 200 and various electronic components. The module printed circuit board 100 may include a substrate 110, horizontal wiring lines 120, vias 130, a first solder mask 140, and a second solder mask 150.

The substrate 110 may extend in a first direction DR1 and a second direction DR2 intersecting each other. For example, the substrate 110 may have a length and a width in the first direction DR1 and the second direction DR2, respectively. The substrate 110 may include a first surface 110a and a second surface 110b spaced apart from each other in a third direction DR3 intersecting the first direction DR1 and the second direction DR2. For example, the first direction DR1, the second direction DR2, and the third direction DR3 may be perpendicular to each other. The substrate 110 may include a first length side surface LS1 and a second length side surface LS2 extending in the first direction DR1 between the first surface 110a and the second surface 110b. The second length side surface LS2 may be spaced apart from the first length side surface LS1 in the second direction DR2. The substrate 110 may include a first width side surface WS1 and a second width side surface WS2 extending in the second direction DR2 between the first surface 110a and the second surface 110b. The second width side surface WS2 may be spaced apart from the first width side surface WS1 in the first direction DR1.

The substrate 110 may include a plurality of sub-layers 112 arranged in the third direction DR3. The first surface 110a may be a surface of the sub-layer 112 positioned last in the third direction DR3, the surface facing the third direction DR3. The second surface 110b may be a surface of the sub-layer 112 first positioned in the third direction DR3, the surface facing a direction opposite to the third direction DR3. The plurality of sub-layers 112 may include an insulating material having mechanical strength and thermal stability. For example, the plurality of sub-layers 112 may include FR4, FR2, CEM1, CEM3, polytetrafluoroethylene (PTFE), or polyimide.

The horizontal wiring lines 120 may be provided between the sub-layers 112, on the first surface 110a, and on the second surface 110b. Hereinafter, the horizontal wiring lines 120 on the first surface 110a and the second surface 110b may be referred to as first horizontal wiring lines 122 and second horizontal wiring lines 124. The horizontal wiring lines 120 positioned between the sub-layers 112 may be referred to as inner horizontal wiring lines. The horizontal wiring lines 120 may extend in a direction parallel to the first surface 110a. For example, the horizontal wiring lines 120 may extend in the first direction DR1, the second direction DR2, or a direction in which the first direction DR1 and the second direction DR2 are combined. The horizontal wiring lines 120 may include a conductive material. For example, the horizontal wiring lines 120 may include copper (Cu) and/or aluminum (Al). The horizontal wiring lines 120 may have required morphological characteristics (e.g., a length, a width, and a thickness). For example, the morphological characteristics of the horizontal wiring lines 120 may be determined to prevent or reduce loss or distortion of a transmission signal. The horizontal wiring lines 120 may be configured to transmit an input signal for the at least one semiconductor chip 200 provided from an outside of the semiconductor module 1000 and an output signal provided from the at least one semiconductor chip 200 or to transmit a driving voltage or a ground voltage to the at least one semiconductor chip 200.

Edge connectors 160 may be provided on the first surface 110a and the second surface 110b of the substrate 110. The edge connectors 160 may be spaced apart from the at least one semiconductor chip 200. The edge connectors 160 may be disposed closer to the first length side surface LS1 than to the second length side surface LS2 of the substrate 110. The edge connectors 160 may be configured to be electrically connected to an electronic device outside the semiconductor module 1000. For example, when the semiconductor module 1000 is coupled to a memory slot, the edge connectors 160 may be configured to be electrically in contact with the memory slot. The edge connectors 160 may include an electrically conductive material. For example, the edge connectors 160 may include copper (Cu).

In some example embodiments, a portion of the edge connectors 160 may be configured to receive an input signal for the at least one semiconductor chip 200 provided from the outside of the semiconductor module 1000 or to transmit an output signal provided from the at least one semiconductor chip 200 to the outside of the semiconductor module 1000. In some example embodiments, another portion of the edge connectors 160 may be electrically connected to a terminal outside the semiconductor module 1000, which supplies the driving voltage to the at least one semiconductor chip 200. In some example embodiments, still another portion of the edge connectors 160 may be configured to be electrically connected to a terminal outside the semiconductor module 1000, which provides the ground voltage to the at least one semiconductor chip 200.

The vias 130 may pass through the substrate 110. For example, the vias 130 may extend in the third direction DR3 in the substrate 110. The vias 130 may be configured to provide electrical connection between components provided at different positions in the third direction DR3. The vias 130 may include an electrically conductive material. For example, the vias 130 may include copper (Cu). For example, the vias 130 may electrically connect the first horizontal wiring lines 122 on the first surface 110a and the second horizontal wiring lines 124 on the second surface 110b. For example, the vias 130 may electrically connect the horizontal wiring lines 120 and the at least one semiconductor chip 200. For example, the vias 130 may electrically connect the horizontal wiring lines 120 and the edge connectors 160.

The first solder mask 140 and the second solder mask 150 may be provided on the first surface 110a and the second surface 110b of the substrate 110, respectively. The first solder mask 140 and the second solder mask 150 may be insulating coating layers. For example, the first solder mask 140 and the second solder mask 150 may include epoxy or acrylic. The first solder mask 140 and the second solder mask 150 may be configured to protect a circuit formed on the substrate 110 from physical damage and chemical damage. For example, the first solder mask 140 and the second solder mask 150 may cover the first horizontal wiring lines 122 and the second horizontal wiring lines 124 formed on the first surface 110a and the second surface 110b of the substrate 110, respectively.

The first solder mask 140 may expose the first surface 110a adjacent to the first width side surface WS1 and the second width side surface WS2. The first surface 110a adjacent to the first width side surface WS1, which is exposed by the first solder mask 140, may be referred to as a first exposure surface ES1. The first surface 110a adjacent to the second width side surface WS2, which is exposed by the first solder mask 140, may be referred to as a second exposure surface ES2.

The second solder mask 150 may expose the second surface 110b adjacent to the first width side surface WS1 and the second width side surface WS2. The second surface 110b adjacent to the first width side surface WS1, which is exposed by the second solder mask 150, may be referred to as a third exposure surface ES3. The second surface 110b adjacent to the second width side surface WS2, which is exposed by the second solder mask 150, may be referred to as a fourth exposure surface ES4.

The first exposure surface ES1, the second exposure surface ES2, the third exposure surface ES3, and the fourth exposure surface ES4 may extend in the second direction DR2. The first exposure surface ES1, the second exposure surface ES2, the third exposure surface ES3, and the fourth exposure surface ES4 may be configured such that the gripper, the first solder mask 140, and the second solder mask 150 are spaced apart from each other when the gripper configured to grip the module printed circuit board 100 grips the module printed circuit board 100 in a semiconductor module manufacturing process.

As illustrated in FIGS. 4 and 5, a gripper GP may be configured to grip an area of the module printed circuit board 100, which is adjacent to the second length side surface LS2. An area of the module printed circuit board 100, which is gripped by the gripper GP may be referred to as a grip area GR. The grip area GR may be an area of the module printed circuit board 100, which overlaps the gripper GP in the first direction DR1 from a viewpoint of the third direction DR3. A size of the grip area GR in the second direction DR2 may be referred to as a grip length GL. In some example embodiments, the grip area GR may be a portion of the module printed circuit board 100. For example, the grip area GR may extend from the second length side surface LS2 to a point before the first length side surface LS1. For example, the grip area GR may extend from the second length side surface LS2 to a point before (or above in the second direction DR2) grooves 102. In some example embodiments, the grip area GR may be the entire module printed circuit board 100. For example, the grip area GR may extend from the second length side surface LS2 to the first length side surface LS1. When the gripper GP grips the module printed circuit board 100, the gripper GP may be in contact with the substrate 110. In some example embodiments, the gripper GP may be in contact with an edge of the substrate 110. For example, the gripper GP may be in contact with an edge between the first length side surface LS1 and the first surface 110a, an edge between the first length side surface LS1 and the second surface 110b, an edge between the second length side surface LS2 and the first surface 110a, and an edge between the second length side surface LS2 and the second surface 110b.

The first exposure surface ES1, the second exposure surface ES2, the third exposure surface ES3, and the fourth exposure surface ES4 may be determined such that the gripper GP, the first solder mask 140, and the second solder mask 150 are spaced apart from each other. In a viewpoint of the third direction DR3, the grip area GR may completely overlap the first exposure surface ES1, the second exposure surface ES2, the third exposure surface ES3, and the fourth exposure surface ES4 in the first direction DR1. In some example embodiments, the first exposure surface ES1, the second exposure surface ES2, the third exposure surface ES3, and the fourth exposure surface ES4 may extend from one end to the other end of the grip area GR in the second direction DR2. For example, a first exposure length EL1, a second exposure length EL2, a third exposure length EL3, and a fourth exposure length EL4 may be the same or substantially the same as the grip length GL. For example, the first exposure surface ES1, the second exposure surface ES2, the third exposure surface ES3, and the fourth exposure surface ES4 may extend from the second length side surface LS2 to a point before the first length side surface LS1. For example, the first exposure surface ES1, the second exposure surface ES2, the third exposure surface ES3, and the fourth exposure surface ES4 may extend from the second length side surface LS2 to a point before the grooves 102. For example, the first exposure surface ES1, the second exposure surface ES2, the third exposure surface ES3, and the fourth exposure surface ES4 may extend from the second length side surface LS2 to the first length side surface LS1.

In some example embodiments, at least one of the first exposure surface ES1, the second exposure surface ES2, the third exposure surface ES3, and the fourth exposure surface ES4 may extend further than the grip area GR in the second direction DR2. For example, the first exposure surface ES1, the second exposure surface ES2, the third exposure surface ES3, and the fourth exposure surface ES4 may extend from the second length side surface LS2 to a position between the grip area GR and the first length side surface LS1. For example, each of the first exposure length EL1, the second exposure length EL2, the third exposure length EL3, and the fourth exposure length EL4 may be greater than the grip length GL. In some example embodiments, an end of at least one of the first exposure surface ES1, the second exposure surface ES2, the third exposure surface ES3, and the fourth exposure surface ES4 may be shifted from the grip area GR in a viewpoint of the third direction DR3. For example, the end of at least one of the first exposure surface ES1, the second exposure surface ES2, the third exposure surface ES3, and the fourth exposure surface ES4 may be positioned between the grip area GR and the first length side surface LS1 in a viewpoint of the third direction DR3.

The first exposure surface ES1 may have the first exposure length EL1 in the second direction DR2 and a first exposure width EW1 in the first direction DR1. The second exposure surface ES2 may have the second exposure length EL2 in the second direction DR2 and a second exposure width EW2 in the first direction DR1. The third exposure surface ES3 may have the third exposure length EL3 in the second direction DR2 and a third exposure width EW3 in the first direction DR1. The fourth exposure surface ES4 may have the fourth exposure length EL4 in the second direction DR2 and a fourth exposure width EW4 in the first direction DR1. In some example embodiments, the first exposure length EL1, the second exposure length EL2, the third exposure length EL3, and the fourth exposure length EL4 may be the same or substantially the same. In some example embodiments, at least two of the first exposure length EL1, the second exposure length EL2, the third exposure length EL3, and the fourth exposure length EL4 may be different from each other. In some example embodiments, the first exposure width EW1, the second exposure width EW2, the third exposure width EW3, and the fourth exposure width EW4 may be the same or substantially the same. In some example embodiments, at least two of the first exposure width EW1, the second exposure width EW2, the third exposure width EW3, and the fourth exposure width EW4 may be different from each other.

The first exposure width EW1, the second exposure width EW2, the third exposure width EW3, and the fourth exposure width EW4 may be determined such that the first solder mask 140 and the second solder mask 150 are spaced apart from the gripper GP and the horizontal wiring lines 120. That is, the first solder mask 140 and the second solder mask 150 do not contact the gripper GP and the horizontal wiring lines 120. A minimum value of the first exposure width EW1, the second exposure width EW2, the third exposure width EW3, and the fourth exposure width EW4 may be greater than a distance in contact with the gripper GP, and a maximum value thereof may be smaller than a distance in contact with the horizontal wiring lines 120. Hereinafter, each exposure width will be described in detail.

In some example embodiments, the gripper GP may have grip surfaces facing the first width side surface WS1 and the second width side surface WS2. Grip surfaces directly adjacent to the first exposure surface ES1, the second exposure surface ES2, the third exposure surface ES3, and the fourth exposure surface ES4 may be referred to as a first grip surface GS1, a second grip surface GS2, a third grip surface GS3, and a fourth grip surface GS4, respectively. The first grip surface GS1, the second grip surface GS2, the third grip surface GS3, and the fourth grip surface GS4 may be inclined from the first exposure surface ES1, the second exposure surface ES2, the third exposure surface ES3, and the fourth exposure surface ES4, respectively. An angle between the first grip surface GS1 and the first exposure surface ES1 may be referred to as a first grip angle “α.” An angle between the second grip surface GS2 and the second exposure surface ES2 may be referred to as a second grip angle “β.” An angle between the third grip surface GS3 and the third exposure surface ES3 may be referred to as a third grip angle “γ.” An angle between the fourth grip surface GS4 and the fourth exposure surface ES4 may be referred to as a fourth grip angle “δ.” In some example embodiments, the first grip angle “α,” the second grip angle “β,” the third grip angle “γ,” and the fourth grip angle “δ” may be the same or substantially the same. For example, the first grip angle “α,” the second grip angle “β,” the third grip angle “γ,” and the fourth grip angle “δ” may be about or exactly 60 degrees (°). In some example embodiments, at least two of the first grip angle “α,” the second grip angle “β,” the third grip angle “γ,” and the fourth grip angle “δ” may be different from each other.

The first exposure width EW1 may be greater than a first contact distance CD1 between the first solder mask 140 and the gripper GP in an area adjacent to the first exposure surface ES1. The first contact distance CD1 may be a minimum distance in the first direction DR1 between the first solder mask 140 and the first width side surface WS1 in which the first solder mask 140 is in contact with the gripper GP in an area adjacent to the first exposure surface ES1. The first contact distance CD1 may be determined by the following equation.

$$CD 1 = \frac{d 1}{tan α}$$

(α: first grip angle, d1: thickness of first solder mask)

The first exposure width EW1 may be smaller than a minimum distance in the first direction DR1 between the first width side surface WS1 and the horizontal wiring lines 120 on the first surface 110a. The minimum distance in the first direction DR1 between the first width side surface WS1 and the horizontal wiring lines 120 on the first surface 110a and a minimum distance in the first direction DR1 between the first width side surface WS1 and the horizontal wiring lines 120 inside the substrate 110 may be independent of each other. In some example embodiments, the horizontal wiring lines 120 on the first surface 110a may be arranged closer to the first width side surface WS1 than the horizontal wiring lines 120 inside the substrate 110. In some example embodiments, the minimum distance in the first direction DR1 between the first width side surface WS1 and the horizontal wiring lines 120 on the first surface 110a and the minimum distance in the first direction DR1 between the first width side surface WS1 and the horizontal wiring lines 120 inside the substrate 110 may be the same or substantially the same. In some example embodiments, the horizontal wiring lines 120 on the first surface 110a may be arranged farther from the first width side surface WS1 than the horizontal wiring lines 120 inside the substrate 110.

For example, when the first grip angle “α” is about or exactly 60 degrees (°) and a thickness of the first solder mask 140 is about or exactly 0.025 millimeters (mm), the first contact distance CD1 may be about or exactly 0.014 millimeters (mm). For example, the minimum distance in the first direction DR1 between the first width side surface WS1 and the horizontal wiring lines 120 on the first surface 110a may be about or exactly 300 millimeters (mm). In some example embodiments, the first exposure width EW1 may be in a range of about or exactly 0.03 millimeters (mm) to about or exactly 0.28 millimeters (mm).

The second exposure width EW2 may be greater than a second contact distance CD2 between the first solder mask 140 and the gripper GP in an area adjacent to the second exposure surface ES2. The second contact distance CD2 may be a minimum distance in the first direction DR1 between the first solder mask 140 and the second width side surface WS2 in which the first solder mask 140 is in contact with the gripper GP in an area adjacent to the second exposure surface ES2. The second contact distance CD2 may be determined by the following equation.

$$CD 2 = \frac{d 1}{tan β}$$

(β: second grip angle, d1: thickness of first solder mask)

The second exposure width EW2 may be smaller than a minimum distance in the first direction DR1 between the second width side surface WS2 and the horizontal wiring lines 120 on the first surface 110a. The minimum distance in the first direction DR1 between the second width side surface WS2 and the horizontal wiring lines 120 on the first surface 110a and a minimum distance in the first direction DR1 between the second width side surface WS2 and the horizontal wiring lines 120 inside the substrate 110 may be independent of each other. In some example embodiments, the horizontal wiring lines 120 on the first surface 110a may be arranged closer to the second width side surface WS2 than the horizontal wiring lines 120 inside the substrate 110. In some example embodiments, the minimum distance in the first direction DR1 between the second width side surface WS2 and the horizontal wiring lines 120 on the first surface 110a and the minimum distance in the first direction DR1 between the second width side surface WS2 and the horizontal wiring lines 120 inside the substrate 110 may be the same or substantially the same. In some example embodiments, the horizontal wiring lines 120 on the first surface 110a may be arranged farther from the second width side surface WS2 than the horizontal wiring lines 120 inside the substrate 110.

For example, when the second grip angle “β” is about or exactly 60 degrees (°) and the thickness of the first solder mask 140 is about or exactly 0.025 millimeters (mm), the second contact distance CD2 may be about or exactly 0.014 millimeters (mm). For example, the minimum distance in the first direction DR1 between the second width side surface WS2 and the horizontal wiring lines 120 on the first surface 110a may be about or exactly 300 millimeters (mm). In some example embodiments, the second exposure width EW2 may be in a range of about or exactly 0.03 millimeters (mm) to about or exactly 0.28 millimeters (mm).

The third exposure width EW3 may be greater than a third contact distance CD3 between the second solder mask 150 and the gripper GP in an area adjacent to the third exposure surface ES3. The third contact distance CD3 may be a minimum distance in the first direction DR1 between the second solder mask 150 and the first width side surface WS1 in which the second solder mask 150 is in contact with the gripper GP in an area adjacent to the third exposure surface ES3. The third contact distance CD3 may be determined by the following equation.

$$CD 3 = \frac{d 2}{tan γ}$$

(γ: third grip angle, d2: thickness of second solder mask)

The third exposure width EW3 may be smaller than a minimum distance in the first direction DR1 between the first width side surface WS1 and the horizontal wiring lines 120 on the second surface 110b. The minimum distance in the first direction DR1 between the first width side surface WS1 and the horizontal wiring lines 120 on the second surface 110b and the minimum distance in the first direction DR1 between the first width side surface WS1 and the horizontal wiring lines 120 inside the substrate 110 may be independent of each other. In some example embodiments, the horizontal wiring lines 120 on the second surface 110b may be arranged closer to the first width side surface WS1 than the horizontal wiring lines 120 inside the substrate 110. In some example embodiments, the minimum distance in the first direction DR1 between the first width side surface WS1 and the horizontal wiring lines 120 on the second surface 110b and the minimum distance in the first direction DR1 between the first width side surface WS1 and the horizontal wiring lines 120 inside the substrate 110 may be the same or substantially the same. In some example embodiments, the horizontal wiring lines 120 on the second surface 110b may be arranged farther from the first width side surface WS1 than the horizontal wiring lines 120 inside the substrate 110.

For example, when the third grip angle “γ” is about or exactly 60 degrees (°) and a thickness of the second solder mask 150 is about or exactly 0.025 millimeters (mm), the third contact distance CD3 may be about or exactly 0.014 millimeters (mm). For example, the minimum distance in the first direction DR1 between the first width side surface WS1 and the horizontal wiring lines 120 on the second surface 110b may be about or exactly 300 millimeters (mm). In some example embodiments, the third exposure width EW3 may be in a range of about or exactly 0.03 millimeters (mm) to about or exactly 0.28 millimeters (mm).

The fourth exposure width EW4 may be greater than a fourth contact distance CD4 between the second solder mask 150 and the gripper GP in an area adjacent to the fourth exposure surface ES4. The fourth contact distance CD4 may be a minimum distance in the first direction DR1 between the second solder mask 150 and the second width side surface WS2 in which the second solder mask 150 is in contact with the gripper GP in an area adjacent to the fourth exposure surface ES4. The fourth contact distance CD4 may be determined by the following equation.

$$CD 4 = \frac{d 2}{tan δ}$$

(δ: fourth grip angle, d2: thickness of second solder mask)

The fourth exposure width EW4 may be smaller than a minimum distance in the first direction DR1 between the second width side surface WS2 and the horizontal wiring lines 120 on the second surface 110b. The minimum distance in the first direction DR1 between the second width side surface WS2 and the horizontal wiring lines 120 on the second surface 110b and the minimum distance in the first direction DR1 between the second width side surface WS2 and the horizontal wiring lines 120 inside the substrate 110 may be independent of each other. In some example embodiments, the horizontal wiring lines 120 on the second surface 110b may be arranged closer to the second width side surface WS2 than the horizontal wiring lines 120 inside the substrate 110. In some example embodiments, the minimum distance in the first direction DR1 between the second width side surface WS2 and the horizontal wiring lines 120 on the second surface 110b and the minimum distance in the first direction DR1 between the second width side surface WS2 and the horizontal wiring lines 120 inside the substrate 110 may be the same or substantially the same. In some example embodiments, the horizontal wiring lines 120 on the second surface 110b may be arranged farther from the second width side surface WS2 than the horizontal wiring lines 120 inside the substrate 110.

For example, when the fourth grip angle “δ” is about or exactly 60 degrees (°) and the thickness of the second solder mask 150 is about or exactly 0.025 millimeters (mm), the fourth contact distance CD4 may be about or exactly 0.014 millimeters (mm). For example, the minimum distance in the first direction DR1 between the second width side surface WS2 and the horizontal wiring lines 120 on the second surface 110b may be about or exactly 300 millimeters (mm). In some example embodiments, the fourth exposure width EW4 may be in a range of about or exactly 0.03 millimeters (mm) to about or exactly 0.28 millimeters (mm).

The at least one semiconductor chip 200 may be provided on the module printed circuit board 100. The at least one semiconductor chip 200 may include at least one of a memory chip (e.g., a random access memory (RAM), a read-only memory (ROM), and a flash memory), a processor chip (e.g., a central processing unit (CPU), a graphic processing unit (GPU), an application processor (AP), and a digital signal processor (DSP)), a logic chip (e.g., an application Specific Integrated Circuit (ASIC) and a field-programmable gate array (FPGA)), an analog signal chip (e.g., an analog-to-digital converter (ADC), a digital-to-analog converter (DAC), and a power management integrated circuit (PMIC)), and a sensor chip (e.g., an image sensor, an acceleration sensor, a temperature sensor). A portion of the at least one semiconductor chip 200 may be mounted on the first surface 110a of the substrate 110. Another portion of the at least one semiconductor chip 200 may be mounted on the second surface 110b of the substrate 110. For example, the at least one semiconductor chip 200 may be mounted on the printed circuit board 100 using a surface mount technology (SMT) or a through-hole technology (THT).

When the gripper GP comes into contact with the first solder mask 140 and the second solder mask 150, the first solder mask 140 and the second solder mask 150 may be damaged. For example, portions of the first solder mask 140 and the second solder mask 150 may be damaged by the gripper GP, and thus particles may be generated. The particles may cause defects in the semiconductor module 1000.

The first solder mask 140 and the second solder mask 150 of the present disclosure may be spaced apart from the gripper GP. Damage to the first solder mask 140 and the second solder mask 150 due to the gripper GP may be prevented or reduced. Generation of the particles caused from the first solder mask 140 and the second solder mask 150 may be prevented or reduced. Accordingly, defects of the semiconductor module 1000 may be reduced.

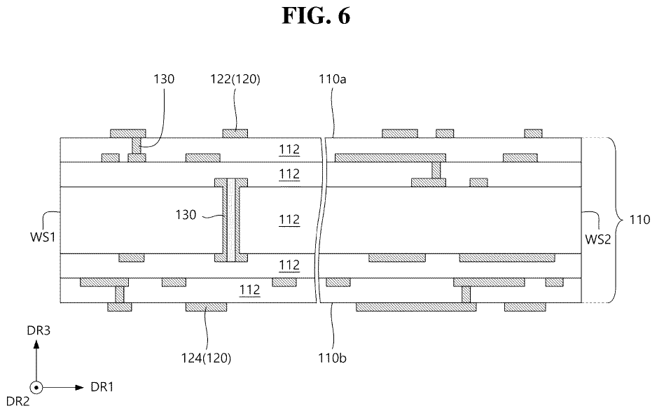

FIGS. 6 to 8 are cross-sectional views corresponding to line A-A′ of FIG. 1 for describing a method of manufacturing a semiconductor module according to some example embodiments. For simplicity of description, the same or substantially the same contents as those described with reference to FIGS. 1 to 5 may not be described.

Referring to FIG. 6, a preliminary module printed circuit board 100 may be formed. The preliminary module printed circuit board 100 may include the substrate 110, the horizontal wiring lines 120, and the vias 130. The substrate 110 may include a plurality of sub-layers 112 arranged in the third direction DR3. The first surface 110a may be a surface of the sub-layer 112 positioned last in the third direction DR3, the surface facing the third direction DR3. The second surface 110b may be a surface of the sub-layer 112 first positioned in the third direction DR3, the surface facing a direction opposite to the third direction DR3. The plurality of sub-layers 112 may include an insulating material having mechanical strength and thermal stability. For example, the plurality of sub-layers 112 may include FR4, FR2, CEM1, CEM3, polytetrafluoroethylene (PTFE), and/or polyimide.

The horizontal wiring lines 120 may be formed between the sub-layers 112, on the first surface 110a, and on the second surface 110b. For example, the horizontal wiring lines 120 may be formed at one surface (e.g., the first surface 110a) and extend into the other surface (e.g., the second surface 110b). In some example embodiments, the horizontal wiring lines 120 may be formed by a process of forming a conductive film and then patterning the conductive layer into a required shape.

The vias 130 may be formed to pass through at least one sub-layer 112. The vias 130 may electrically connect the horizontal wiring lines formed at different positions in the third direction DR3. In some example embodiments, the vias 130 may be formed by a process of forming holes at required positions, then performing a plating process, and forming a conductive film in the holes.

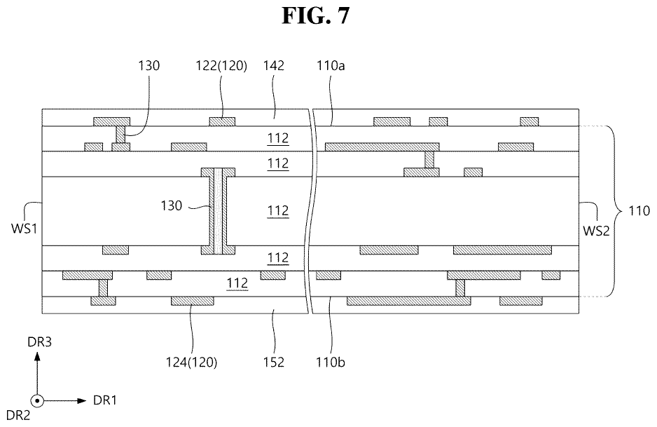

Referring to FIG. 7, a first preliminary solder mask 142 and a second preliminary solder mask 152 may be formed on the first surface 110a and the second surface 110b, respectively. The first preliminary solder mask 142 and the second preliminary solder mask 152 may include epoxy or acrylic. The first preliminary solder mask 142 and the second preliminary solder mask 152 may be formed to cover the entire first surface 110a and the entire second surface 110b, respectively. In some example embodiments, the first preliminary solder mask 142 and the second preliminary solder mask 152 may be applied onto the first surface 110a and the second surface 110b, respectively. For example, the applying process may be performed using a screen printing method, a curtain coating method, or a spray coating method.

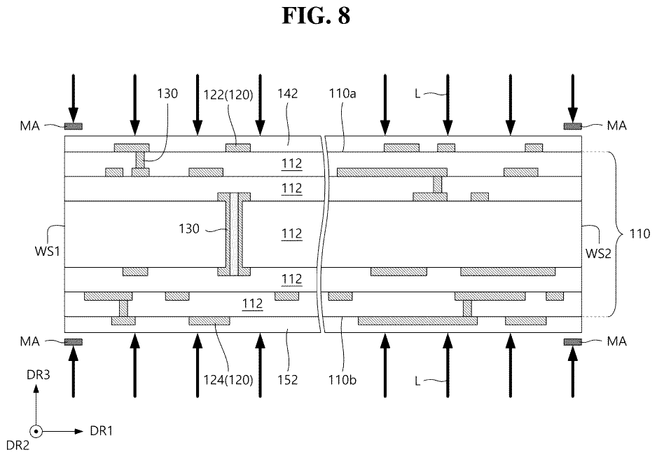

Referring to FIG. 8, the first preliminary solder mask 142 and the second preliminary solder mask 152 may be exposed. For example, the exposure process may include radiating light “L” (e.g., ultraviolet light) to required portions of the first preliminary solder mask 142 and the second preliminary solder mask 152 using a mask MA that shields light. Exposed portions of the first preliminary solder mask 142 and the second preliminary solder mask 152 may be cured. Unexposed portions may not be cured.

The unexposed portions may be formed on the first exposure surface ES1, the second exposure surface ES2, the third exposure surface ES3, and the fourth exposure surface ES4 described with reference to FIGS. 1 to 5. In some example embodiments, a size of the unexposed portion on the first exposure surface ES1 in the first direction DR1 and a size thereof in the second direction DR2 may be the same or substantially the same as the first exposure length EL1 and the first exposure width EW1 described with reference to FIGS. 1 to 5, respectively. In some example embodiments, a size of the unexposed portion on the second exposure surface ES2 in the first direction DR1 and a size thereof in the second direction DR2 may be the same or substantially the same as the second exposure length EL2 and the second exposure width EW2 described with reference to FIGS. 1 to 5, respectively. In some example embodiments, a size of the unexposed portion on the third exposure surface ES3 in the first direction DR1 and a size thereof in the second direction DR2 may be the same or substantially the same as the third exposure length EL3 and the third exposure width EW3 described with reference to FIGS. 1 to 5, respectively. In some example embodiments, a size of the unexposed portion on the fourth exposure surface ES4 in the first direction DR1 and a size thereof in the second direction DR2 may be the same or substantially the same as the fourth exposure length EL4 and the fourth exposure width EW4 described with reference to FIGS. 1 to 5, respectively.

Referring back to FIG. 3, the first solder mask 140 and the second solder mask 150 may be formed. The forming of the first solder mask 140 and the second solder mask 150 may include performing a development process on the first preliminary solder mask 142 and the second preliminary solder mask 152. Uncured portions (e.g., unexposed portions) of the first preliminary solder mask 142 and the second preliminary solder mask 152 may be removed by the developing process on the first preliminary solder mask 142 and the second preliminary solder mask 152. The uncured portions may be removed so that the first exposure surface ES1, the second exposure surface ES2, the third exposure surface ES3, and the fourth exposure surface ES4 may be exposed. The first solder mask 140 and the second solder mask 150 may be formed on the preliminary module printed circuit board 100 to form the module printed circuit board 100.

After the first solder mask 140 and the second solder mask 150 are formed, a subsequent process of forming the semiconductor chip 200 and electronic elements on the module printed circuit board 100 may be performed. When the subsequent process is performed, the gripper GP may grip the module printed circuit board 100 to move the module printed circuit board 100 to a required position or fix a position thereof.

The first solder mask 140 and the second solder mask 150 of the present disclosure may be formed to be spaced apart from the gripper GP when the gripper GP grips the module printed circuit board 100. Accordingly, the first solder mask 140 and the second solder mask 150 may not be damaged or have reduced damage by the gripper GP, and generation of particles caused from the first solder mask 140 and the second solder mask 150 may be prevented or reduced. Accordingly, defects of the semiconductor module 1000 may be reduced.

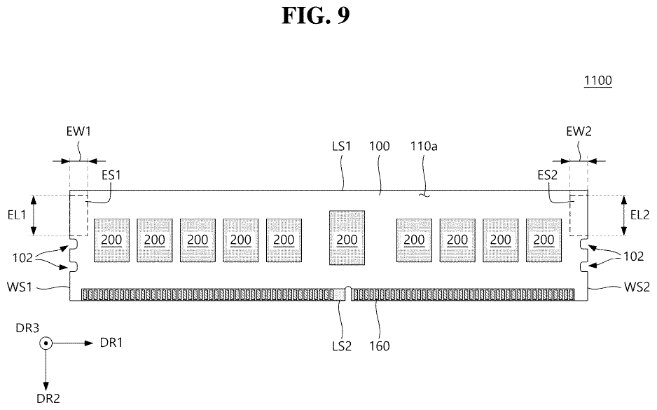

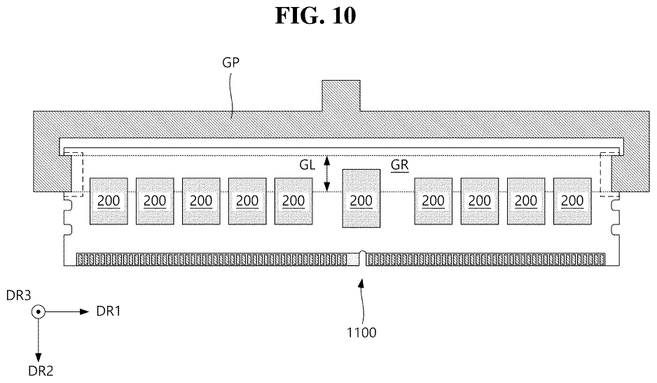

FIG. 9 is a plan view of the semiconductor module according to some example embodiments. FIG. 10 is a plan view corresponding to FIG. 9 for describing the state in which the gripper grips the module printed circuit board. For simplicity of description, substantially the same contents as those described with reference to FIGS. 1 to 5 may not be described.

Referring to FIGS. 9 to 10, a semiconductor module 1100 may be provided. Unlike those described with reference to FIGS. 1 to 5, the first exposure surface ES1 and the second exposure surface ES2 may be spaced apart from an edge between the second length side surface LS2 and the first surface 110a, and the third exposure surface ES3 and the fourth exposure surface ES4 may be spaced apart from an edge between the second length side surface LS2 and the second surface 110b. The first solder mask 140 may be provided on the first surface 110a between the first exposure surface ES1 and the second length side surface LS2. The first solder mask 140 may be provided on the first surface 110a between the second exposure surface ES2 and the second length side surface LS2. The second solder mask 150 may be provided on the second surface 110b between the third exposure surface ES3 and the second length side surface LS2. The second solder mask 150 may be provided on the second surface 110b between the fourth exposure surface ES4 and the second length side surface LS2.

The gripper GP may be configured to grip an area between the first length side surface LS1 and the second length side surface LS2. For example, the gripper GP may be configured to grip an area between the first length side surface LS1 and the groove 102. The gripper GP may be in contact with an edge between the first exposure surface ES1 and the first width side surface WS1, an edge between the second exposure surface ES2 and the second width side surface WS2, an edge between the third exposure surface ES3 and the first width side surface WS1, and an edge between the fourth exposure surface ES4 and the second width side surface WS2. Accordingly, the first solder mask 140 and the second solder mask 150 may be spaced apart from the gripper GP. Damage to the first solder mask 140 and the second solder mask 150 due to the gripper GP may be prevented or reduced. Generation of the particles caused from the first solder mask 140 and the second solder mask 150 may be prevented or reduced. Accordingly, defects of the semiconductor module 1100 may be reduced.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C, or any combination thereof. Likewise, A and/or B means A, B, or A and B. While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

According to some example embodiments, a semiconductor module includes a module printed circuit board; and a semiconductor chip mounted on the module printed circuit board, the module printed circuit board including a substrate including a first surface and a second surface on opposite sides and components embedded within the substrate; wiring lines on the first surface electrically connected to the components; and a first solder mask on the wiring lines and the first surface, the first solder mask exposing a first exposure surface and a second exposure surface of the first surface, the first exposure surface and the second exposure surface being along opposite edges of the substrate. According to some example embodiments, the semiconductor module further includes the first exposure surface having a first exposure width in the first direction, the first exposure width determined such that an angle between a plane extending from the first edge and passing through the first solder mask and the first exposure surface is smaller than a first grip angle, and the first grip angle being an angle between a first grip surface of a gripper configured to grip the module printed circuit board and the first exposure surface, the first grip surface being in contact with the first edge.

The present disclosure may provide semiconductor modules that improve defects.

The present disclosure may provide methods of manufacturing a semiconductor module that improve defects.

However, the effects of the present disclosure are not limited to the above disclosure.

The above description of some example embodiments of the technical spirit of the present disclosure provides some examples for describing the technical spirit of the present disclosure. Thus, it is obvious that the technical spirit of the present disclosure is not limited to the above embodiments, and various modifications and changes may be made by those skilled in the art by combining the above embodiments within the technical spirit of the present disclosure.

What is claimed is:

1. A semiconductor module comprising:
a module printed circuit board; and
a semiconductor chip mounted on the module printed circuit board,
the module printed circuit board including
a substrate including a first surface and a second surface on opposite sides;
first horizontal wiring lines on the first surface; and
a first solder mask on the first horizontal wiring lines, and
the first solder mask configured to expose a first exposure surface and a second exposure surface of the first surface spaced apart from each other in a first direction.

2. The semiconductor module of claim 1, wherein
the substrate further includes a first width side surface and a second width side surface that are spaced apart from each other in the first direction and extend in a second direction intersecting the first direction,
the first exposure surface extends from a first edge between the first surface and the first width side surface in the first direction, and
the second exposure surface extends from a second edge between the first surface and the second width side surface in a direction opposite to the first direction.

3. The semiconductor module of claim 2, wherein
the first exposure surface has a first exposure width in the first direction,
the first exposure width is determined such that an angle between a plane extending from the first edge and passing through the first solder mask and the first exposure surface is smaller than a first grip angle, and
the first grip angle is an angle between a first grip surface of a gripper configured to grip the module printed circuit board and the first exposure surface, the first grip surface being in contact with the first edge.

4. The semiconductor module of claim 3, wherein the first exposure width is smaller than a minimum distance the first solder mask exposes the first horizontal wiring lines adjacent to the first exposure surface.

5. The semiconductor module of claim 3, wherein
the second exposure surface has a second exposure width in the first direction,
the second exposure width is determined such that an angle between a plane extending from the second edge and passing through the first solder mask and the second exposure surface is smaller than a second grip angle, and
the second grip angle is an angle between a second grip surface of the gripper and the second exposure surface, the second grip surface being in contact with the second edge.

6. The semiconductor module of claim 2, wherein
the module printed circuit board includes:
second horizontal wiring lines on the second surface; and
a second solder mask on the second horizontal wiring lines,
the second solder mask is configured to expose a third exposure surface and a fourth exposure surface of the second surface spaced apart from each other in the first direction, and
the third exposure surface and the fourth exposure surface overlap the first exposure surface and the second exposure surface in a third direction intersecting the first direction and the second direction, respectively.

7. The semiconductor module of claim 6, wherein
the third exposure surface extends in the first direction from a third edge between the second surface and the first width side surface, and
the fourth exposure surface extends in a direction opposite to the first direction from a fourth edge between the second surface and the first width side surface.

8. The semiconductor module of claim 7, wherein
the third exposure surface and the fourth exposure surface have a third exposure width and a fourth exposure width in the first direction, respectively,
the third exposure width is determined such that an angle between a plane extending from the third edge and passing through the second solder mask and the third exposure surface is smaller than a third grip angle,
the fourth exposure width is determined such that an angle between a plane extending from the fourth edge and passing through the second solder mask and the fourth exposure surface is smaller than a fourth grip angle, and
the third grip angle and the fourth grip angle are an angle between a third grip surface of a gripper configured to grip the module printed circuit board, the third grip surface being in contact with the third edge, and the third exposure surface and an angle between a fourth grip surface thereof in contact with the fourth edge and the fourth exposure surface, respectively.

9. The semiconductor module of claim 1, wherein
the substrate further includes a first length side surface extending in the first direction, and
the first exposure surface and the second exposure surface extend in a second direction from an edge between the first length side surface and the first surface.

10. The semiconductor module of claim 9, wherein
the substrate further includes a first groove and a second groove at opposite ends in the first direction and spaced apart from each other in the first direction,
the first exposure surface extends from the edge between the first length side surface and the first surface to a point before the first groove, and
the second exposure surface extends from the edge between the first length side surface and the first surface to a point before the second groove.

11. The semiconductor module of claim 1, wherein
the substrate further includes a first length side surface extending in the first direction, and
the first exposure surface and the second exposure surface are spaced apart from an edge between the first length side surface and the first surface.

12. The semiconductor module of claim 1, wherein
the module printed circuit board further includes inner horizontal wiring lines inside the substrate and extending in the first direction and a second direction intersecting the first direction, and
some of the inner horizontal wiring lines overlap the first exposure surface in a third direction intersecting the first direction and the second direction.

13. The semiconductor module of claim 1, wherein
the module printed circuit board further includes inner horizontal wiring lines inside the substrate and extending in the first direction and a second direction intersecting the first direction, and
the inner horizontal wiring lines are spaced apart from an area overlapping the first exposure surface in a third direction intersecting the first direction and the second direction.

14. A semiconductor module comprising:
a module printed circuit board; and
semiconductor chips mounted on the module printed circuit board,
the module printed circuit board including
a substrate including a first surface and a second surface on opposite sides;
first horizontal wiring lines and second horizontal wiring lines on the first surface and the second surface;
a first solder mask and a second solder mask on the first horizontal wiring lines and the second horizontal wiring lines; and
a plurality of edge connectors spaced apart from the semiconductor chips,
the first solder mask configured to expose a first exposure surface and a second exposure surface of the first surface spaced apart from each other in a first direction parallel to the first surface, and
the second solder mask configured to expose a third exposure surface and a fourth exposure surface of the second surface spaced apart from each other in the first direction.

15. The semiconductor module of claim 14, wherein
the substrate further includes a first length side surface extending in the first direction and a first groove and a second groove at opposite ends in the first direction and spaced apart from each other in the first direction,
the first exposure surface and the second exposure surface extend from an edge between the first length side surface and the first surface to the first groove and the second groove, respectively, and
the third exposure surface and the fourth exposure surface extend from an edge between the first length side surface and the second surface to a point before the first groove and the second groove, respectively.

16. A method of manufacturing a semiconductor module, the method comprising:
forming a preliminary module printed circuit board including a substrate including a first surface and a second surface on opposite sides, first horizontal wiring lines on the first surface, second horizontal wiring lines on the second surface, and a plurality of vias extending in a thickness direction of the substrate;
forming a first solder mask and a second solder mask on the first surface and the second surface, respectively, to form a module printed circuit board; and
mounting a semiconductor chip on the module printed circuit board,
the first solder mask exposing a first exposure surface and a second exposure surface of the first surface spaced apart from each other in a first direction parallel to the first surface.

17. The method of claim 16, wherein the forming of the first solder mask includes:
applying a first preliminary solder mask onto the first surface;
selectively exposing a required area of the first preliminary solder mask; and
exposing the first exposure surface and the second exposure surface of the first surface by removing a remaining area of the first preliminary solder mask except for the exposed area.

18. The method of claim 17, wherein the forming of the second solder mask includes:
applying a second preliminary solder mask onto the second surface;
selectively exposing a required area of the second preliminary solder mask; and
exposing a third exposure surface and a fourth exposure surface of the second surface are spaced apart from each other in the first direction, by removing a remaining area of the second preliminary solder mask except for the exposed area.

19. The method of claim 16, wherein
the substrate includes a first edge and a second edge spaced apart from each other in the first direction and extending in a second direction intersecting the first direction,
the first exposure surface extends from the first edge in the first direction, and
the second exposure surface extends from the second edge in a direction opposite to the first direction.

20. The method of claim 19, wherein
the first exposure surface and the second exposure surface have a first exposure width and a second exposure width in the first direction,
the first exposure width is determined such that an angle between a plane extending from the first edge and passing through the first solder mask and the first exposure surface is smaller than a first grip angle,
the second exposure width is determined such that an angle between a plane extending from the second edge and passing through the first solder mask and the second exposure surface is smaller than a second grip angle, and
the first grip angle and the second grip angle are an angle between a first grip surface of a gripper configured to grip the module printed circuit board, the first grip surface being in contact with the first edge, and the first exposure surface, and an angle between a second grip surface thereof in contact with the second edge and the second exposure surface, respectively.
